(19) United States
(12) Patent Application Publication
(10) Pub. No.: US 2009/0084582 A1
(43) Pub. Date: Apr. 2, 2009

(54) Printed circuit board having stepped conduction layer

(75) Inventors: Han Kim, Yongin-si (KR); Hyung-Sik Choi, Hwaseong-si (KR); Dae-Hyun Park, Jung-gu (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/010,750

(22) Filed: Jan. 29, 2008

(30) Foreign Application Priority Data
Sep. 28, 2007 (KR) 10-2007-0097721

(51) Int. Cl. H05K 1/00

(52) U.S. Cl. 174/250

(57) ABSTRACT

A printed circuit board having a stepped conduction layer is disclosed. In one embodiment of the invention, a printed circuit board is provided in which at least one conduction layer configured for use as a signal transmission layer is divided into at least two base regions and at least one connecting region connecting any adjacent two of the base regions, where the connecting region is stepped to a lower height than those of the base regions. The stepped conduction layer in the printed circuit board can be used to resolve the problem of mixed signals in a printed circuit board equipped with various parts and components, including an analog circuit and digital circuit, etc.

### CROSS-REFERENCE TO RELATED APPLICATIONS

This application claims the benefit of Korean Patent Application No. 10-2007-0097721 filed with the Korean Intellectual Property Office on Sep. 28, 2007, the disclosure of which is incorporated herein by reference in its entirety.

### BACKGROUND

1. Technical Field

The present invention relates to a printed circuit board, more particularly to a printed circuit board having a stepped conduction layer.

2. Description of the Related Art

Portability has become a critical feature of current electronic devices, and various devices allowing wireless communication have appeared in the market, such as mobile communication terminals, PDA's (personal digital assistants), laptops, DMB (digital multimedia broadcasting) equipment, etc.

To enable wireless communication, such devices generally include printed circuit boards that have both analog circuits (for example, an RF circuit) and digital circuits.

FIG. 1 is a cross-sectional view of a printed circuit board that includes an analog circuit and a digital circuit. While FIG. 1 illustrates a printed circuit board 100 that has a four-layer structure, printed circuit boards of various other structures are possible, for example those having two layers, six layers, etc. Here, it will be assumed that the analog circuit is an RF circuit.

The printed circuit board 100 may include metal layers 110-1, 110-2, 110-3, 110-4 (referred to collectively by the reference numeral 110), and dielectric layers 120-1, 120-2, 120-3 (referred to collectively by the reference numeral 120), as well as a digital circuit 130 and an RF circuit 140 mounted on the uppermost metal layer 110-1.

Assuming that the metal layer 110-2 is a ground layer and the metal layer 110-3 is a power layer, an electric current may flow through vias 160 formed between the ground layer 110-2 and power layer 110-3, and the printed circuit board 100 can be made to perform a pre-configured action or function.

Here, due to the harmonics and the operating frequency of the digital circuit 130, electromagnetic (EM) waves 150 may be transferred to the RF circuit 140, to incur the problems of mixed signals. The problem of mixed signals refers to the situation in which the EM waves of the digital circuit 130 has a frequency within the operating frequency band of the RF circuit 140, so that the RF circuit 140 is hindered in operating correctly. For example, when the RF circuit 140 receives a signal in a particular frequency band, EM waves 150 that include signals within the corresponding frequency band may be transferred from the digital circuit 130, making it difficult to accurately receive signals within the corresponding frequency band.

This problem of mixed signals is becoming harder to resolve, as the electronic devices are growing in complexity and the operating frequencies of the digital circuit 130 are continuously increasing.

The method of using a decoupling capacitor, a typical means of resolving power noise, is not a suitable solution at high frequencies, and thus there is a need for research on structures that attenuate noise between the RF circuit and the digital circuit at high frequencies.

Accordingly, the coplanar EBG structure (coplanar electromagnetic bandgap structure) has recently been developed to address the problem of mixed signals between a digital circuit and an analog circuit. The coplanar EBG structure generally has the form of EBG cells, which do not allow the transmission of particular frequencies, formed repeatedly over the ground layer.

FIG. 2A illustrates a perspective view of a printed circuit board having a coplanar EBG structure according to the related art, while FIG. 2B illustrates a top view of the printed circuit board having a coplanar EBG structure illustrated in FIG. 2A.

FIGS. 2A and 2B present a printed circuit board that includes a first metal layer 210, a dielectric layer 230, and a second metal layer 220, where the second metal layer 220 can be divided into first regions 220a, which have a relatively larger width, and second regions 220b, which have a relatively narrower width. Here, any two first regions 220a are electrically connected by a second region 220b having a narrow width, and this arrangement is repeated over the entire area of the second metal layer 220. This structure is referred to as a coplanar EBG structure, and by arranging such a coplanar EBG structure on a conduction layer that is to be used as a signal transmission layer (e.g. power layer, ground layer, etc.), the structure may serve as a band-rejection filter capable of attenuating noise in a particular frequency band. The reason for this will be explained below with reference to FIG. 2C.

As can easily be observed in FIG. 2C, in second metal layer 220, the first regions 220a having a relatively larger width (X of FIG. 2C) form low-impedance regions, while the second regions 220b having a relatively narrower width (Y of FIG. 2C) form high-impedance regions. In this way, the coplanar EBG structure may have the form of low-impedance regions and high-impedance regions alternating in order, and may thereby perform the function of attenuating the transfer of signals or noise of a particular frequency band.

As described above, the coplanar EBG structure according to the related art has the form of broader regions and narrower regions formed repeatedly over a power layer or ground layer, which will serve as a signal transmission layer. However, in the related art as described above, in order to obtain a high impedance value through a region having a narrow width, the pattern has to be given a long shape, as illustrated in FIG. 2D (220b of FIG. 2D). Thus, the related art generally requires larger areas for forming long patterns, which presents design restrictions in the manufacture of boards.

The design restrictions may be especially serious in cases involving a complicated wiring structure, such as in the main board of a cell phone, where the digital circuit and RF circuit are implemented on the same board, or in cases where numerous active and passive components, etc., are applied on a board of a small size, such as in a SIP (system in package) board.

Therefore, there is a need for a technology with which to implement higher impedance values for the same given area and to obtain more accurate noise attenuation.

### SUMMARY

As such, an aspect of the invention aims to provide a printed circuit board having a stepped conduction layer, in which a stepped conduction layer may be used as an electromagnetic bandgap (EBG) structure to resolve the problem of mixed signals in a printed circuit board equipped with various parts and components, including an analog circuit and digital circuit, etc.

Another aspect of the invention aims to provide a printed circuit board having a stepped conduction layer, in which a stepped conduction layer may be used as an EBG structure to attenuate noise of a particular frequency band in a simple manner.

Also, still another aspect of the invention aims to provide a printed circuit board having a stepped conduction layer, which can be implemented as a smaller, thinner, and lighter printed circuit board, and which allows reduced manufacture times and manufacture costs.

One aspect of the invention provides a printed circuit board having a stepped conduction layer. In the printed circuit board, at least one conduction layer configured for use as a signal transmission layer is divided into at least two base regions and at least one connecting region connecting any adjacent two of the base regions, where the connecting region is stepped to a lower height than those of the base regions. That is, the connecting region is formed as a lower step with respect to the base regions.

Here, the conduction layer can be used as a power layer or a ground layer.

A lower surface or an upper surface of the connecting region may lie on the same plane as a lower surface or an upper surface of the base region, or a lower surface or an upper surface of the connecting region may lie on a different plane from a lower surface or an upper surface of the base region.

When viewed from a side of the conduction layer, the connecting region may connect two adjacent base regions in a straight shape or in a concavely curved shape.

The shape of the base regions may circular, oval, or polygonal, when viewed from above the conduction layer.

On the other hand, the connecting region may be in a solid stripe pattern, a dotted stripe pattern, or a checked pattern, when viewed from above the conduction layer.

The connecting region may be configured to connect two adjacent base regions at the corners of the two adjacent base regions, when viewed from above the conduction layer.

There may be multiple connecting regions formed on the conduction layer, where the connecting regions may be designed to have gradually decreasing or increasing thicknesses in at least one direction.

A bridge connecting structure between the connecting regions and the base regions may be repeated alternately in the conduction layer.

A bridge connecting structure between the connecting regions and the base regions may be disposed in possible noise transfer paths between a noise source and a noise attenuation target positioned on the printed circuit board.

Here, the printed circuit board may be such that has at least one digital circuit and at least one analog circuit mounted, where the noise source and the noise attenuation target may correspond respectively to one and the other of positions where the digital circuit and the analog circuit are to be mounted.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view of a printed circuit board that includes an analog circuit and a digital circuit.

FIG. 2A is a perspective view of a printed circuit board having a coplanar EBG structure according to the related art.

FIG. 2B is a top view of the printed circuit board having a coplanar EBG structure illustrated in FIG. 2A.

FIG. 2C is a diagram for explaining the principles of how the coplanar EBG structure of FIG. 2A can be used as an electromagnetic bandgap structure.

FIG. 2D is a drawing illustrating another form of a coplanar EBG structure according to the related art.

FIG. 3 is a side view of a printed circuit board having a stepped conduction layer according to a first disclosed embodiment of the invention.

FIG. 4 is a top view of the stepped conduction layer in the printed circuit board illustrated in FIG. 3.

FIG. 5A and FIG. 5B are diagrams for explaining the principles of how the printed circuit board having a stepped conduction layer according to an aspect of the invention can be used as an electromagnetic bandgap structure.

FIG. 6A is a side view of a printed circuit board having a stepped conduction layer according to a second disclosed embodiment of the invention.

FIG. 6B is a side view of a printed circuit board having a stepped conduction layer according to a third disclosed embodiment of the invention.

FIG. 6C is a side view of a printed circuit board having a stepped conduction layer according to a fourth disclosed embodiment of the invention.

FIG. 7A, FIG. 7B, and FIG. 7C are top views of the stepped conduction layer according to an aspect of the invention for several example arrangements of the base regions.

FIG. 8A, FIG. 8B, and FIG. 8C are top views of the stepped conduction layer according to an aspect of the invention for several example arrangements of the connecting regions.

FIG. 9A, FIG. 9B, and FIG. 9C are top views of the stepped conduction layer according to an aspect of the invention for several other example arrangements of the connecting regions.

FIG. 10A is a drawing of a simulation model for verifying the applicability of the stepped conduction layer according to an aspect of the invention as an electromagnetic bandgap structure.

FIG. 10B is a graph representing computer simulation results when applying the simulation model illustrated in FIG. 10A.

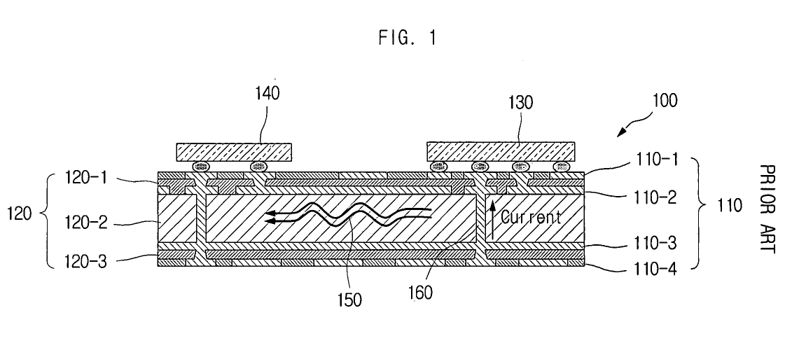

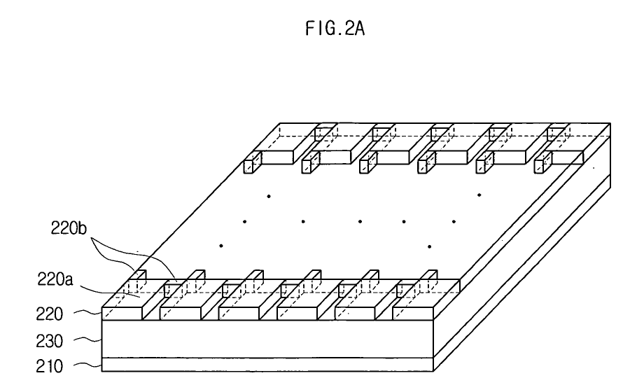

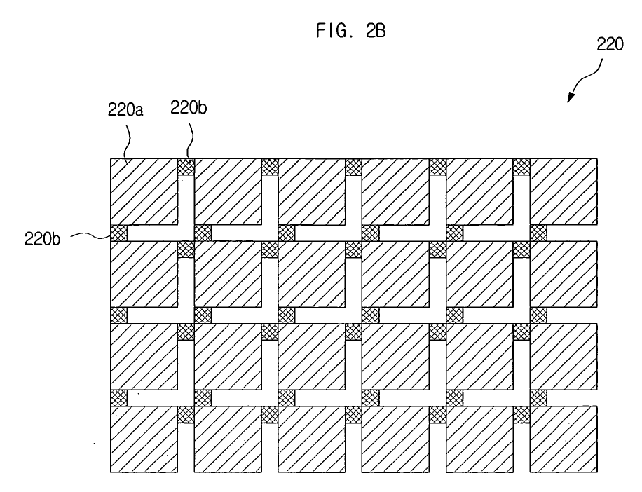

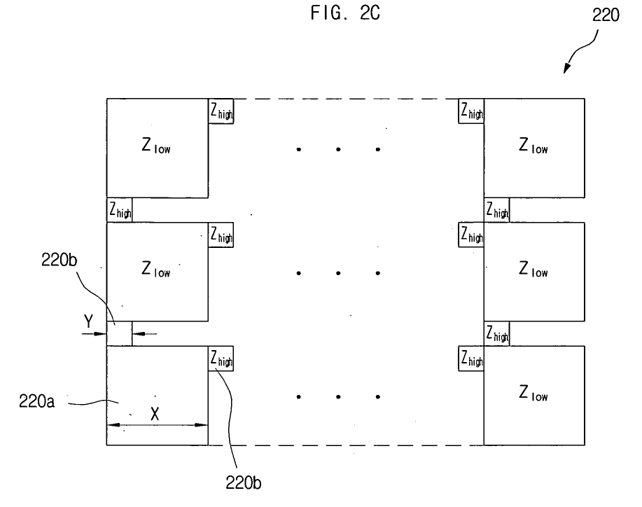

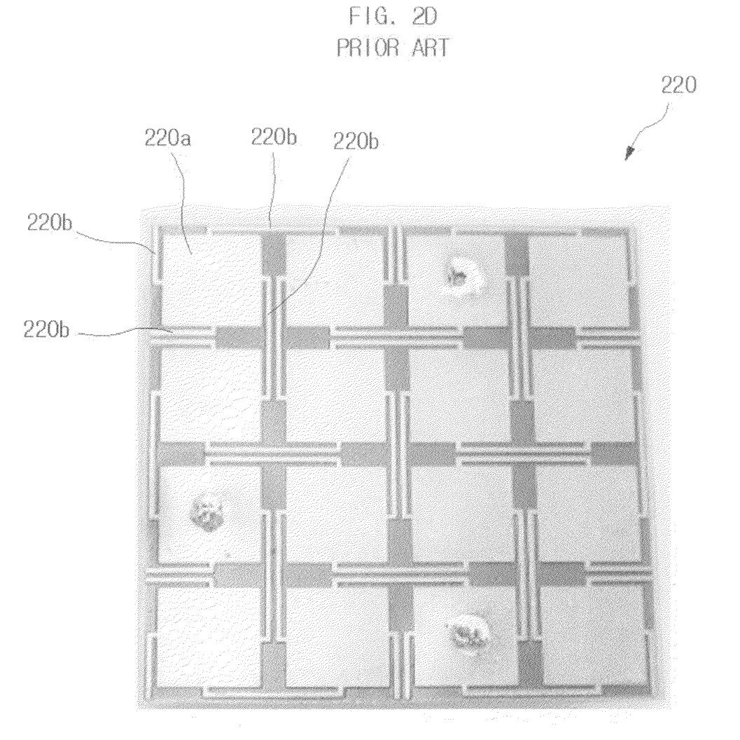

### DETAILED DESCRIPTION

As the present invention allows for various changes and numerous embodiments, particular embodiments will be illustrated in drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first” and “second,” etc., may be used to describe various elements, such elements must not be limited to the above terms. The above terms are used only to distinguish one element from another. For example, a first element may be referred to as a second element without departing from the scope of rights of the present invention, and likewise a second element may be referred to as a first element. The term “and/or” encompasses both combinations of the plurality of related items disclosed and any one item from among the plurality of related items disclosed.

When an element is mentioned to be “connected to” or “accessing” another element, this may mean that it is directly formed on or stacked on the other element, but it is to be understood that another element may exist in-between. On the other hand, when an element is mentioned to be “directly connected to” or “directly accessing” another element, it is to be understood that there are no other elements in-between.

The terms used in the present application are merely used to describe particular embodiments, and are not intended to limit the present invention. An expression used in the singular encompasses the expression of the plural, unless it has a clearly different meaning in the context. In the present application, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Unless otherwise defined, all terms used herein, including technical or scientific terms, have the same meanings as those generally understood by those with ordinary knowledge in the field of art to which the present invention belongs. Such terms as those defined in a generally used dictionary are to be interpreted to have the meanings equal to the contextual meanings in the relevant field of art, and are not to be interpreted to have ideal or excessively formal meanings unless clearly defined in the present application.

Certain embodiments of the invention will be described below in more detail with reference to the accompanying drawings, in which redundant explanations are omitted for those contents that can be applied equally to each of the embodiments.

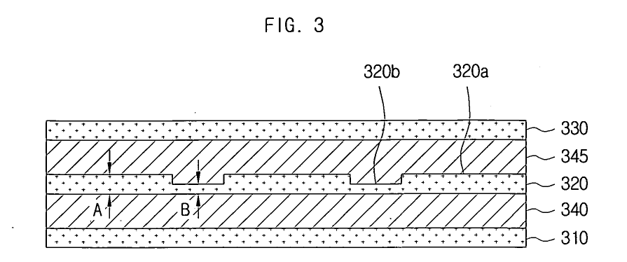

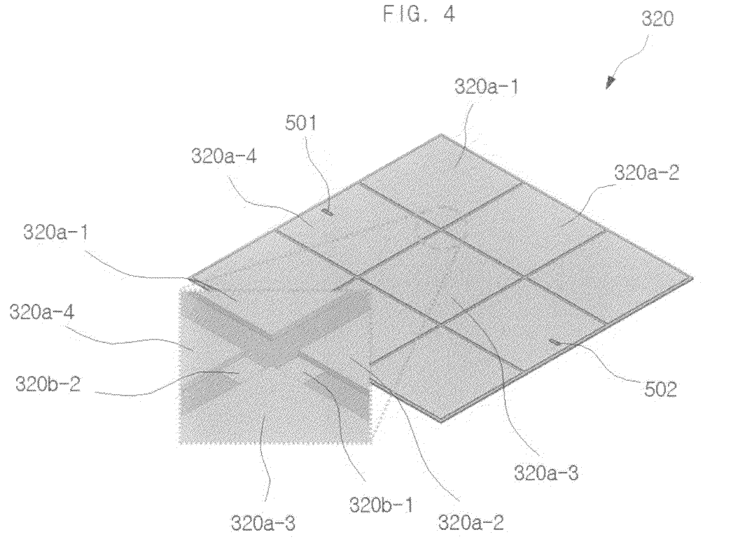

FIG. 3 is a side view of a printed circuit board having a stepped conduction layer according to a first disclosed embodiment of the invention, and FIG. 4 is a view of the stepped conduction layer in the printed circuit board illustrated in FIG. 3 when seen from the top.

In FIG. 3, a printed circuit board is illustrated that includes a first conduction layer 310, a first dielectric layer 340, a second conduction layer 320, a second dielectric layer 345, and a third conduction layer 330.

Looking at the second conduction layer 320, it is seen that two types of regions may be formed in repetition which have different layer thicknesses. That is, the second conduction layer 320 can be divided into first regions having a relatively large thickness (A of FIG. 3) and second regions having a relatively smaller thickness (B of FIG. 3). In other words, the first regions, which have a pre-configured layer thickness, and the second regions, which have a relatively lower height than that of the first regions, may be positioned together in one conduction layer.

Here, the first regions having the relatively greater layer thickness in the second conduction layer 320 will be referred to hereinafter as base regions 320a, in that they maintain the original layer thickness of the second conduction layer 320. Conversely, the second regions having the relatively thinner layer thickness in the second conduction layer 320 will be referred to as connecting regions 320b, in that they have the form of connecting two adjacent base regions 320a when viewing the second conduction layer 320 from the side.

For example, in FIG. 4, a third base region 320a-3 is electrically connected with an adjacent second base region 320a-2 by a first connecting region 320b-1, and with an adjacent fourth base region 320a-4 by a second connecting region 320b-2.

Of course, the method of connecting any two adjacent base regions 320a using a connecting region 320b is not limited to that illustrated in FIG. 4, and various patterns will be given as examples in the drawings described later. However, since all of the base regions 320a may be electrically connected to function as a single signal line, the connecting regions 320b may be such that a closed path is maintained in the connection of the base regions 320a.

As such, the multiple number of base regions 320a may all be electrically connected via the connecting regions 320b, to form a single conduction layer overall. Here, the conduction layer may be a layer that will subsequently be used as a signal transmission layer in the printed circuit board, examples of which include a power layer and a ground layer.

As described above, it can be seen from FIGS. 3 and 4 that, in a printed circuit board having a stepped conduction layer according to an aspect of the invention, a conduction layer that will function as a signal transmission layer may be divided into base regions 320a and connecting regions 320b that have different layer thicknesses respectively. Furthermore, the conduction layer may take the form of two adjacent base regions 320a connected by a connecting region 320b, which is stepped to a relatively lower height, in the shape of a bridge (This structure will hereinafter be referred to as a “thin bridge connection structure.”).

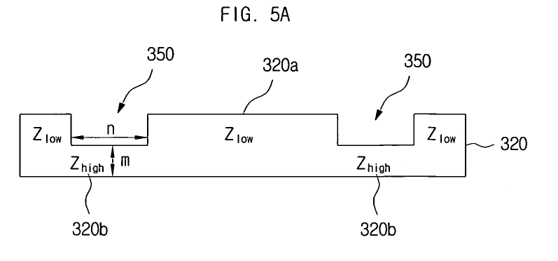

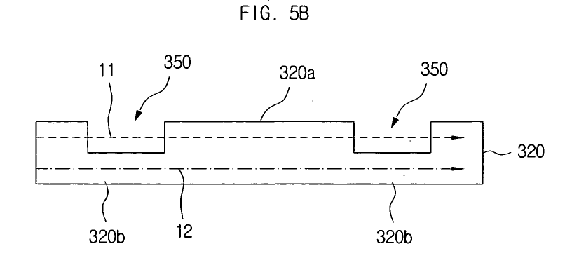

A description will now be given, with reference to FIG. 5A and FIG. 5B, on the principles of how the stepped bridge connection structure described above according to an aspect of the invention can be utilized as an electromagnetic bandgap structure for attenuating the transfer of noise in a particular frequency band. For easier explanation, the second conduction layer 320 of FIGS. 3 and 4 will be referred to simply as the “signal layer,” and the same reference numeral will be used.

FIG. 5A illustrates a side view of a portion of the signal layer 320. Here, the base regions 320a, which have relatively greater layer thicknesses, have low impedance values, while the connecting regions 320b, which are relatively smaller layer thicknesses than the base regions 320a, have higher impedance values. The impedance value of a connecting region 320b will be inversely proportional to the layer thickness (m of FIG. 5A), and directly proportional to the connection length (n of FIG. 5A), and thus may be increased or decreased accordingly. In other words, the impedance of a connecting region 320b can be controlled to have a greater value by decreasing the layer thickness of the connecting region 320b in relation to those of the base regions 320a, and by increasing the connection length.

This is similar to the coplanar EBG structure according to the related art described above. That is, the stepped bridge connection structure, used in embodiments of the invention, also has regions of low impedance value and high impedance value alternately repeated in a low-high-low-high configuration. However, the structure according to the related does not involve differences in layer thickness between regions of low impedance value and high impedance value, and instead provides differences in impedance value by using different areas or widths for the respective regions.

In comparison, embodiments of the invention allow precise control over the impedance values of the base regions 320a and connecting regions 320b by adjusting not only the areas and widths, etc., of the regions but also the layer thickness and connection lengths. Therefore, when an EBG structure is implemented for the same given area and space, the structures according to embodiments of the invention can provide higher impedance values than can the structures according to the related art. As such, embodiments of the invention can readily be applied to a printed circuit board having limited space and area. Moreover, a target frequency band can be attenuated with greater accuracy and precision, as a greater number of design elements are used (area, width, layer thickness, connection length, etc.).

When two types of regions that have different impedance values are arranged in alternation, as illustrated in FIG. 5A, these may function as a sort of band-rejection filter and may attenuate noise of a particular frequency band. Among the signals transmitted through the signal layer 320, a high-frequency signal 11 may travel through only the base regions 320a having low impedance values, while a low-frequency signal 12 may travel through the connecting regions 320b having high impedance values, as illustrated in FIG. 5B. The reason for this is as follows.

In the etched space 350 created after forming the pattern for the connecting regions 320b in the signal layer 320, a dielectric material will be filled in, and as a result, any two adjacent base regions 320a and the etched space 350 in-between may function as a sort of capacitor (of a form having electrodes on both sides of a dielectric material) from the perspective of signals. In addition, a connecting region 320b that connects any two adjacent base regions 320a may function as a sort of inductor from the perspective of signals.

Therefore, a high-frequency signal 11 may pass unhindered through the dielectric material filled in the etched space 350 to travel between two adjacent base regions 320a, while a low-frequency signal 12 may travel between the two adjacent base regions 320a using the inductance provided by the connecting region 320b. Consequently, a signal in a particular frequency band that does not correspond to either of the two cases above cannot be transmitted through the signal layer 320 having a stepped bridge connection structure according to certain embodiments of the invention. Accordingly, as certain embodiments of the invention attenuate the signals and noise of a target frequency band based on the “structural characteristics” of the printed circuit board in which a conduction layer used as a signal transmission layer is formed as a stepped bridge connection structure, it can be said that a structure according to these embodiments function as an electromagnetic bandgap structure.

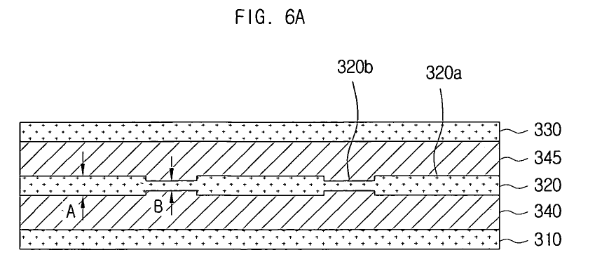

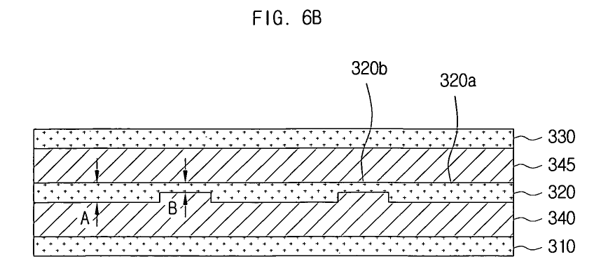

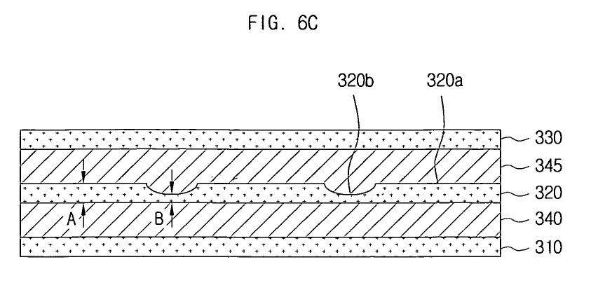

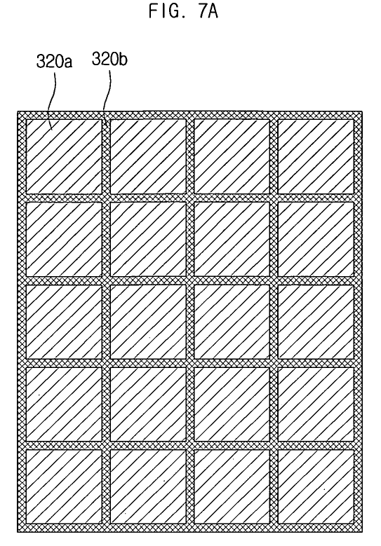

Examples of other embodiments of the invention are illustrated in FIG. 6A through FIG. 10A, and the descriptions that follow will focus mainly on the characteristics of each embodiment.

FIGS. 6A to 6C are side views of printed circuit boards having stepped conduction layers according to certain embodiments of the invention.

Referring to FIG. 6A, viewing the signal layer 320 from the side, the upper and lower surfaces of the connecting regions 320b may lie on different planes from the upper and lower surfaces of the adjacent base regions 320a (i.e. the base regions 320a may be connected at the middle portions). This is different from the example described for FIGS. 3 to 5B, in which the lower surfaces of the connecting regions 320b may lie on the same plane as the lower surfaces of the base regions 320a.

Also, in the case of FIG. 6B, viewing the signal layer 320 from the side, the upper surfaces of the connecting regions 320b may lie on the same plane as the upper surfaces of the base regions 320a. Of course, it is to be appreciated that various other configurations are possible, in which the connecting regions 320b are formed with relatively lower heights compared to the surrounding base regions 320a.

In the case of FIG. 6C, viewing the signal layer 320 from the side, a connecting region 320b may connect two adjacent base regions 320a in the shape of a concave curve (or in an embossed shape). This is different from the examples in the previous drawings, in which the connecting regions 320b connect the base regions 320a in the shape of a substantially straight line.

Furthermore, while the drawings described above illustrate the connecting regions 320b as having the same layer thickness, the invention is not thus limited. That is, the connecting regions 320b may be designed to have gradually decreasing or increasing thicknesses in any one or more direction.

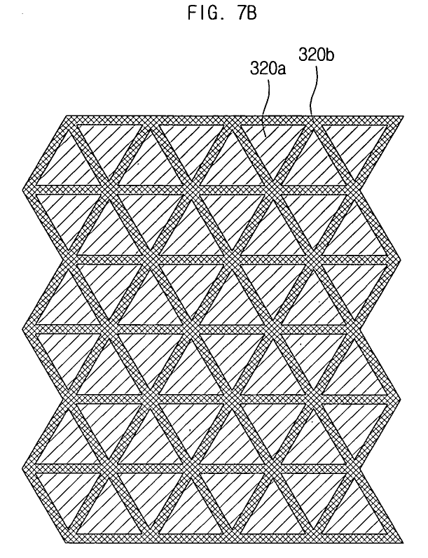

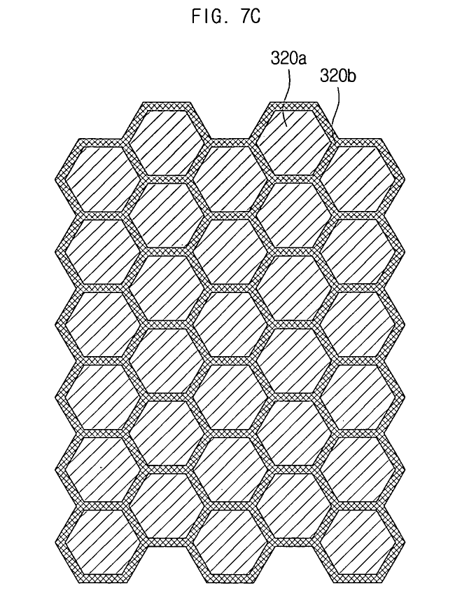

FIG. 7A through FIG. 7C illustrate examples of base region 320a shapes according to certain embodiments of the invention, when viewed from above the signal layer 320. Referring to FIGS. 7A to 7C, viewing the signal layer 320 from above, it can be seen that the base regions 320a can be shaped as squares, triangles, and hexagons. Of course, it is apparent that the shapes are not thus limited, and other shapes may be used such as circular, oval, and other polygonal shapes. The shapes of the base regions 320a can be determined according to what kind of etched patterns the connecting regions 320b are given in the signal layer 320.

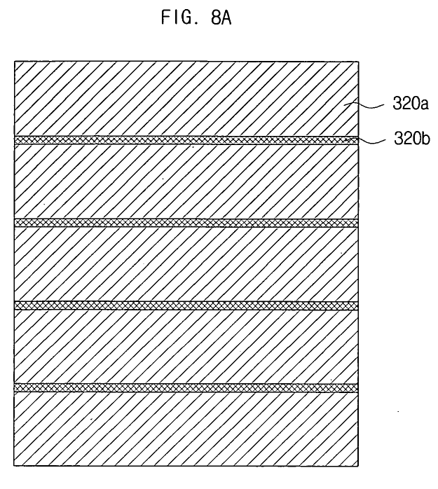

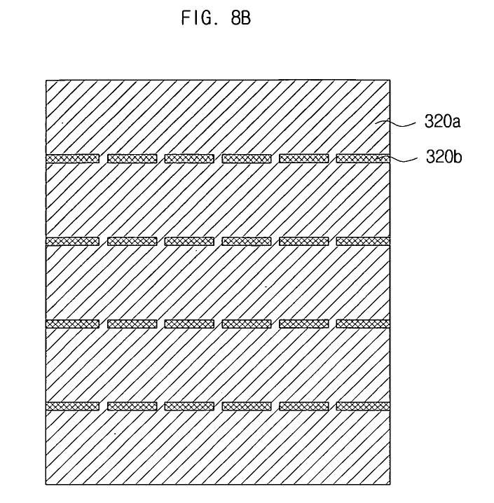

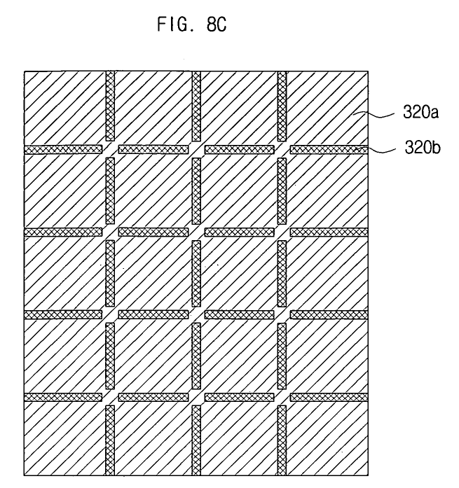

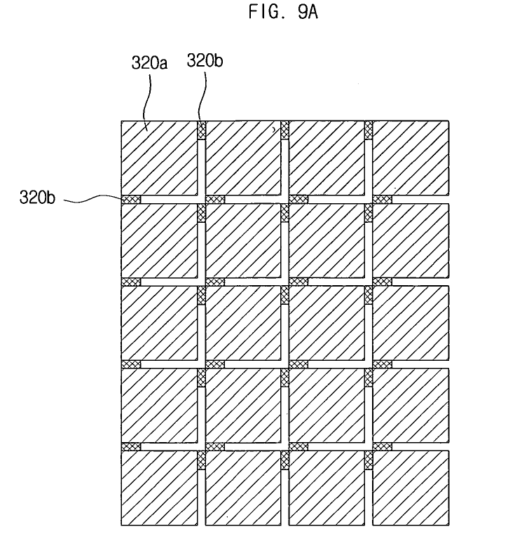

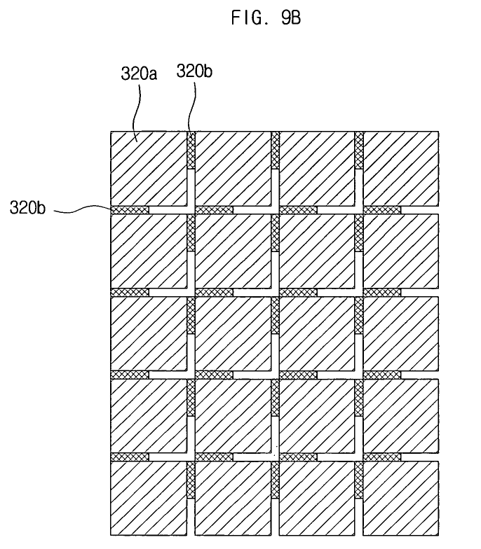

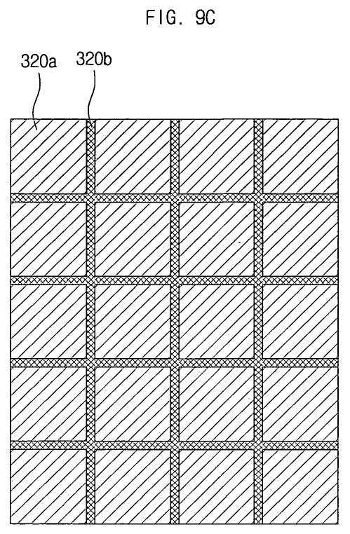

For example, FIG. 8A through FIG. 9C give examples of various etched patterns for forming the connecting regions 320b.

Viewing the signal layer 320 from above, the connecting regions 320b may be formed by an etched pattern shaped as solid stripes in the example shown in FIG. 8A, the connecting regions 320b may be formed by an etched pattern shaped as perforated stripes in the example shown in FIG. 8B, and the connecting regions 320b may be formed by an etched pattern shaped as a checked pattern in the example shown in FIG. 8C.

On the other hand, in the examples shown in FIGS. 9A and 9B, a connecting region 320b connects two adjacent base regions 320a at only a corner of each base region 320a. The connecting regions 320b as shown in FIG. 9A and FIG. 9B can be obtained using a method of forming an etch pattern (shaped as a chess board) in the signal layer 320 as in FIG. 9C, and then additionally adjusting the partial etching depths during the etching process.

As such, the signal layer or conduction layer having the stepped bridge connection structure according to certain embodiments of the invention can be implemented in a simple manner using the same method as that used in the related art, by performing an etching process such as of forming a pattern and afterwards treating with electroless copper plating, etc. Thus, the embodiments of the invention can provide simpler manufacturing processes and reduced manufacturing times and costs.

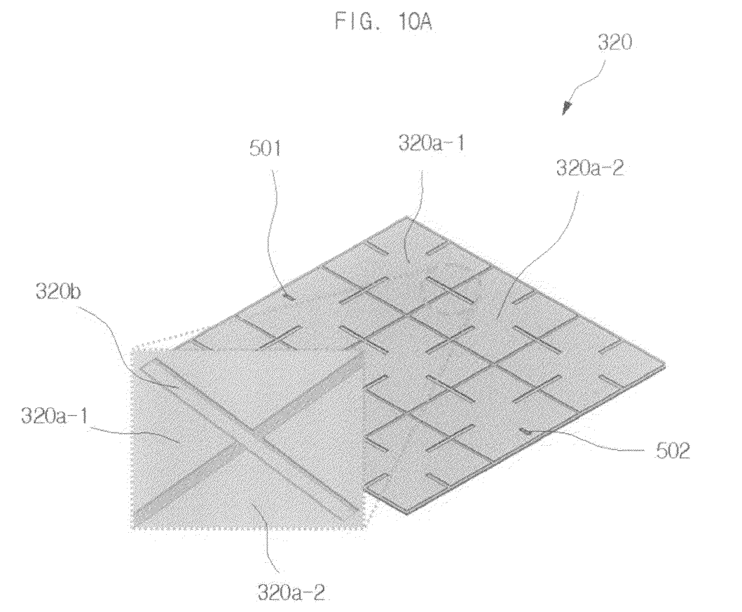

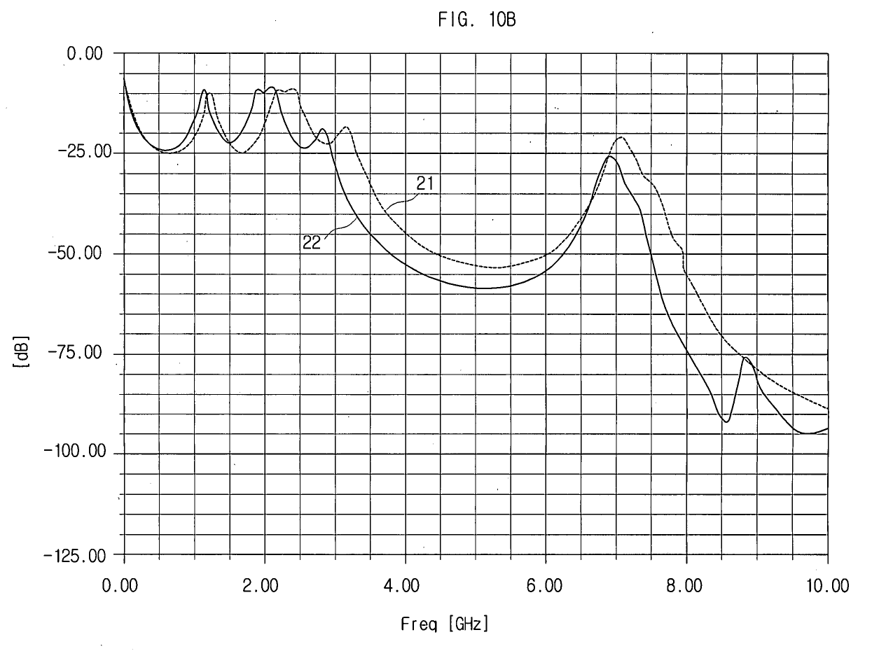

FIG. 10A is a drawing of a simulation model for verifying the applicability of the stepped conduction layer according to an aspect of the invention as an electromagnetic bandgap structure, and FIG. 10B is a graph representing computer simulation results when applying the simulation model illustrated in FIG. 10A.

A noise point 501 and a measurement point 502 were assigned in the simulated signal layer 320 of FIG. 10A, where the graph of FIG. 10B illustrates the results of computer simulations that observe how much of the noise generated at the noise point 501 reaches the measurement point 502. Here, it was assumed that the base regions 320a of the signal layer 320 have a layer thickness of 50 μm, while the connecting regions 320b have a layer thickness of 5 μm.

FIG. 10B illustrates the results for a coplanar EBG structure according to the related art (21 of FIG. 10B) and a stepped bridge connection structure according to an embodiment of the invention (22 of FIG. 10B), both of which were implemented with the same design dimensions.

Referring to FIG. 10B, for the structure according to the related art, it is seen that for an attenuation of −50 dB or greater, the bandgap frequency is about 4.5˜6 GHz. In comparison, in the case of the structure based on an embodiment of the invention, the bandgap frequency is about 3.6˜6.4 GHz for an attenuation of −50 dB or greater. It should be noted that for the same frequency band, better attenuation is obtained for the structure according to an embodiment of the invention. Thus, the simulation results of FIG. 10B prove that the use of the stepped bridge connection structure according to certain embodiments of the invention improve attenuation efficiency compared to the related art under the same conditions.

While the simulation results of FIG. 10B show the bandgap frequency of about 3.6˜6.4 GHz for the structure based on an embodiment of the invention, it is to be appreciated that this may vary according to changes in design parameters, such as the layer thicknesses, widths, areas, shapes, etc., of the base regions 320a, and the layer thicknesses, pattern shapes, connection lengths, widths, areas, etc., of the connecting regions 320b. Thus, by adequately adjusting the design conditions and design parameters described above, it is possible to attenuate noise in a target frequency band, and to resolve the problem of mixed signals between a digital circuit and analog circuit.

For example, by positioning the stepped bridge connection structure according to certain embodiments of the invention in possible noise transfer paths between a noise source and a noise attenuation target in a printed circuit board, the problem of mixed signals described above can be resolved.

As described above, in certain embodiments of the invention, the signal layer or conduction layer, which has a stepped bridge connection structure, can itself be utilized as an electromagnetic bandgap structure, to attenuate a target frequency band. In addition, certain embodiments of the invention can greatly alleviate restrictions in design and difficulties in arrangement, while providing better properties in terms also of signal integrity.

According to certain aspects of the invention as set forth above, a printed circuit board having a stepped conduction layer can be used to resolve the problem of mixed signals in a printed circuit board equipped with various parts and components, including an analog circuit and digital circuit, etc.

Also, by using a stepped conduction layer as an electromagnetic bandgap structure, the noise of a particular frequency band can be attenuated in a simple manner.

Furthermore, embodiments of the invention make it possible to manufacture smaller, thinner, and lighter printed circuit boards, and can simplify manufacturing processes while reducing manufacturing times and manufacturing costs.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A printed circuit board, wherein at least one conduction layer configured for use as a signal transmission layer is divided into at least two base regions and at least one connecting region connecting any adjacent two of the base regions, and wherein the connecting region is stepped to a lower height than those of the base regions.

2. The printed circuit board having a stepped conduction layer according to claim 1, wherein the conduction layer is configured for use as a power layer or a ground layer.

3. The printed circuit board having a stepped conduction layer according to claim 1, wherein a lower surface or an upper surface of the connecting region lies on a same plane as a lower surface or an upper surface of the base region, or the lower surface and the upper surface of the connecting region lies on a different plane from the lower surface and the upper surface of the base region.

4. The printed circuit board having a stepped conduction layer according to claim 1, wherein the connecting region connects the two adjacent base regions in a straight shape or in a concavely curved shape, when viewed from a side of the conduction layer.

5. The printed circuit board having a stepped conduction layer according to claim 1, wherein the base region has any one shape from among a circular shape, an oval shape, and a polygonal shape, when viewed from above the conduction layer.

6. The printed circuit board having a stepped conduction layer according to claim 1, wherein the connecting region has any one pattern among a solid stripe pattern, a perforated stripe pattern, and a checked pattern, when viewed from above the conduction layer.

7. The printed circuit board having a stepped conduction layer according to claim 1, wherein the connecting region connects the two adjacent base regions at a corner of each of the two adjacent base regions, when viewed from above the conduction layer.

8. The printed circuit board having a stepped conduction layer according to claim 1, wherein a plurality of connecting regions are formed on the conduction layer, and wherein the plurality of connecting regions are designed to have gradually decreasing or increasing thicknesses in at least one direction.

9. The printed circuit board having a stepped conduction layer according to claim 1, wherein a bridge connecting structure between the connecting region and the base regions is alternately repeated in the conduction layer.

10. The printed circuit board having a stepped conduction layer according to claim 1, wherein a bridge connecting structure between the connecting regions and the base regions are disposed in possible noise transfer paths between a noise source and a noise attenuation target positioned on the printed circuit board.

11. The printed circuit board having a stepped conduction layer according to claim 10, wherein the printed circuit board is configured to have at least one digital circuit and at least one analog circuit mounted thereon,
and wherein the noise source and the noise attenuation target correspond respectively to one and the other of positions where the digital circuit and the analog circuit are to be mounted.
